(19) United States
(12) Patent Application Publication
(10) Pub. No.: US 2013/0088245 A1
(43) Pub. Date: Apr. 11, 2013

(54) Capacitive Inspection Of EUV Photomasks

(71) Applicant: KLA-Tencor Corporation, Milpitas, CA (US)

(72) Inventor: Abdurrahman Sezginer, Monte Sereno, CA (US)

(73) Assignee: KLA-TENCOR CORPORATION, Milpitas, CA (US)

(21) Appl. No.: 13/647,037

(22) Filed: Oct. 8, 2012

Related U.S. Application Data
(60) Provisional application No. 61/545,356, filed on Oct. 10, 2011.

(51) Int. Cl. G01R 27/26

(52) U.S. Cl. 324/679

(57) ABSTRACT

Methods and systems for generating an indication of a changing electrostatic field between a sense electrode of a capacitance sensing integrated circuit and a specimen under inspection are presented. The capacitance sensing integrated circuit is an integrated circuit that includes a number of sense electrodes and sense electronics. By fabricating the elements of the capacitance sensing integrated circuit as a single microelectronic chip, the sense electrodes can be miniaturized to sizes that enable inspection of fine line patterns common in modern semiconductor manufacturing. In one embodiment, the sense electrodes are metallic contacts. In another embodiment the sense electrodes are field effect transistors (FETs) with a floating gate. The sense electronics generate an indication of the changing electrostatic field between each sense electrode and a specimen under inspection as the specimen is scanned relative to the capacitance sensing integrated circuit.

### CROSS REFERENCE TO RELATED APPLICATION

The present application for patent claims priority under 35 U.S.C. §119 from U.S. provisional patent application Ser. No. 61/545,356, entitled “Capacitive Inspection of EUV Photomasks,” filed Oct. 10, 2011, the subject matter of which is incorporated herein by reference.

### TECHNICAL FIELD

The described embodiments relate to systems for inspection of patterned surfaces, and more particularly to inspection of reticles used in the lithography process of semiconductor manufacturing.

### BACKGROUND INFORMATION

Semiconductor devices such as logic and memory devices are typically fabricated by a sequence of processing steps applied to a substrate or wafer. The various features and multiple structural levels of the semiconductor devices are formed by these processing steps. For example, lithography, among others, is one semiconductor fabrication process that involves generating a pattern on a semiconductor wafer. Additional examples of semiconductor fabrication processes include, but are not limited to, chemical-mechanical polishing, etch, deposition, and ion implantation.

Inspection processes are used at various steps during a semiconductor manufacturing process to detect defects on wafers to promote higher yield. As design rules and process windows continue to shrink in size, inspection systems are required to detect smaller defects on wafer surfaces while maintaining high throughput.

Photolithographic processes use photomasks or reticles and an associated light source to project a circuit image onto a wafer. A high production yield requires masks and reticles with no printing defects. Reticle manufacturing may include a number of different steps such as pattern generation. Patterns may be written with electron beams. Direct write electron beam systems may be used to manufacture complex reticles since they produce fine line resolution. Since it is inevitable that defects will occur, masks and reticles must be inspected to find the defects so that they can be repaired prior to use. As design rules and process windows continue to shrink in size, inspection systems are required to capture a wider range of physical defects on reticle surfaces while maintaining high throughput.

Lithographic tools utilizing Extreme Ultra-Violet (EUV) light sources are able to image smaller features on a wafer. As minimum pattern sizes shrink and integrated circuits are designed with higher device densities, defects that were once tolerable may no longer be acceptable. For example, a single defect may be repeated in each die in lithographic systems and may kill every die in single-die reduction reticles. In addition, VLSI and ULSI-level integrated circuit manufacturing require substantially defect-free and dimensionally perfect reticles due to the critical dimension (CD) budget of such manufacturing. For example, the overall CD budget for such integrated circuits may be approximately 10% or better thereby resulting in a CD budget for a reticle with about a 4% error margin.

Defects may result from incorrect pattern design and/or flaws introduced into the patterns during the pattern generation process. Even if the design is correct, and the pattern generation process is performed satisfactorily, defects in the reticle may be generated by the reticle fabrication process as well as during subsequent processing and handling. For example, particulate matter may also be introduced to the reticle during processing and/or handling of the reticle. This is a particularly acute problem for reticles used in the EUV lithography process. At this time, there is no material available to construct a suitable pellicle to protect an EUV reticle surface from the environment.

EUV photomasks may be inspected by optical microscopy techniques. The photomask may be imaged using Deep Ultra-Violet (DUV) light (e.g., 193 nm wavelength) or EUV light (e.g., 13.5 nm wavelength). The signal to noise ratio of a DUV inspection microscope will be increasingly challenged as the feature size of integrated circuits becomes smaller than 20 nm on wafer and 80 nm on the mask (assuming a lithographic system with 4× magnification). Inspection systems with EUV light sources have not reached maturity and will likely be costly to build and operate.

EUV photomasks may also be inspected by electron microscopy. Electron microscopes scan a focused electron beam on the surface of the photomask. Scattered or secondary electrons are detected. An image of the photomask is formed by plotting the detected electron current versus the position of the focused beam. Electron beam microscopes suffer from poor throughput (i.e., slow scanning speed). Multiple electron beams may be employed to reduce the inspection time, but at a cost of increased cost and complexity.

Other types of microscopy may be considered for inspection of EUV photomasks. These include scanning-tunneling microscopy, atomic-force microscopy, and ion-beam microscopy. These methods have excellent resolution but are too slow for economical inspection of photomasks. For example, both scanning-tunneling microscopy and atomic force microscopy require a probe to be located within atomic dimensions of the surface under inspection. For EUV reticles with patterned surface features that are approximately 60 nanometers in height, the probes (either STM or AFM) must be meticulously traversed over the patterned surface features within atomic dimensions. This slows inspection throughput down to unacceptable levels.

Accordingly, it would be advantageous to develop high throughput methods and/or systems for inspecting wafers or reticles, particularly EUV reticles at sufficiently high resolution.

### SUMMARY

Methods and systems for inspecting a specimen with a capacitance sensing integrated circuit are presented.

In one aspect, the capacitance sensing integrated circuit is an integrated circuit that includes a number of sense electrodes and sense electronics. By fabricating the elements of the capacitance sensing integrated circuit as a single microelectronic chip, the sense electrodes can be miniaturized to sizes that enable inspection of fine line patterns common in modern semiconductor manufacturing. In some embodiments, each sense electrode has a sensing surface with an area of less than 100 um² (e.g., 10 micrometers by 10 micrometers). In some embodiments, sense electrode 101 has a sensing surface with an area of less than 0.01 um² (e.g., 100 nanometers by 100 nanometers). In some other embodiments, sense electrode 101 has a sensing surface with an area of less than 0.0004 um² (e.g., 20 nm by 20 nm).

A voltage is provided across the electrically conductive surface of a specimen and a capacitance sensing integrated circuit. The voltage potential, V0, induces electric fields 107 between the specimen 110 and each sense electrode 101. For a constant voltage potential, V0, between each sense electrode 101 and specimen 110, the induced electric field 107 is stronger when a sense electrode 101 is over the top of a feature and weaker when the electrode is over a trench. Thus, the capacitance between the electrically conductive surface of the specimen 110 and each of the sense electrodes 101 is determined as the specimen 110 is moved relative to the capacitance sensing integrated circuit 100.

In some embodiments, sense electronics maintain a constant voltage potential, V0, between each sense electrode 101 and specimen 110 as the distance between each sense electrode 101 and the surface of specimen 110 changes. As the distance increases (e.g., when sense electrode 101 is over a trench), the electric field is reduced to maintain the constant voltage potential, V0. Since the surface charge density on the sense electrode is proportional to the electric field 107, the total charge on the sense electrode decreases as the distance increases. An electrical current flow transports electrical charge away from the surface of sense electrode to reduce the charge on the surface of sense electrode. Conversely, when the distance decreases (e.g., when sense electrode moves over the top of a feature, the electric field is increased to maintain the constant voltage potential, V0. The electric field is increased by increasing the charge on the surface of sense electrode. An electrical current flow transports electrical charge toward the surface of sense electrode to increase the charge on the surface of sense electrode. A voltage present on an output node of the sense electronics indicates changes in charge on the surface of a sense electrode.

In some embodiments, sense electrodes are metallic contacts (e.g., tungsten, copper, aluminum silicon copper alloy, etc.) common in semiconductor fabrication. Each sense electrode is coupled to a charge amplifier. The charge amplifier maintains a constant voltage potential between a sense electrode and the surface of a specimen under inspection. A voltage present on an output node of the charge amplifier indicates changes in charge on the surface of sense electrode.

In some other embodiments, the sense electrodes are field effect transistors (FET). The gate of each FET is electrically floating (i.e., it is not electrically coupled to an electronic circuit). For a fixed charge present on the floating gate, the gate voltage changes as the distance between the sense electrode and the electrically conductive surface of the specimen changes. As the gate voltage changes the effective resistance or voltage across the source and drain of each FET changes. In some embodiments this is measured as a voltage drop across a resistor coupled in series with the FET and a voltage supply. In some other embodiments, this is measured as a voltage drop across the source and drain of a FET coupled to a current source. In some examples, the change in voltage is detected by a differential amplifier. A voltage present on the output node of the differential amplifier indicates the voltage at the sense electrode.

In another aspect, a number of sense electrodes are selectively coupled to a single amplifier. This may be desirable if there is not enough space on the integrated circuit to individually connect each sense electrode to a distinct amplifier circuit.

In yet another aspect, the effective resolution of a capacitance sensing integrated circuit is enhanced by offsetting the pattern of sense electrodes, skewing the patterns of sense electrodes relative to the scan direction, or a combination of both.

In yet another aspect, the measurement noise associated with signals generated by capacitance sensing integrated circuit may be reduced by employing either homodyne or heterodyne detection techniques.

The foregoing is a summary and thus contains, by necessity, simplifications, generalizations, and omissions of detail. Consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a simplified diagram illustrative of a system 150 including a capacitance sensing integrated circuit 100 to inspect a specimen 110 having an electrically conductive surface.

FIG. 2 is a simplified diagram illustrative of a capacitance sensing integrated circuit 100 in one embodiment.

FIG. 3 is a simplified diagram illustrative of a capacitance sensing integrated circuit 100 in another embodiment.

FIG. 4 is a simplified diagram illustrative of a capacitance sensing integrated circuit 100 in a further embodiment.

FIG. 5 is a simplified diagram illustrative of a capacitance sensing integrated circuit 100 having a staggered array 140 of sense electrodes.

FIG. 6 is a simplified diagram illustrative of a capacitance sensing integrated circuit 100 having a skewed array 140 of sense electrodes.

FIG. 7 is a simplified diagram illustrative of a system including a capacitance sensing integrated circuit 100 to inspect a specimen 110 employing homodyne detection in one embodiment.

FIG. 8 is a flowchart illustrative of a method 200 of determining an indication of a capacitance between a number of sense electrodes and an electrically conductive surface of a specimen as the specimen is scanned relative to capacitance sensing integrated circuit.

### DETAILED DESCRIPTION

Reference will now be made in detail to background examples and some embodiments of the invention, examples of which are illustrated in the accompanying drawings.

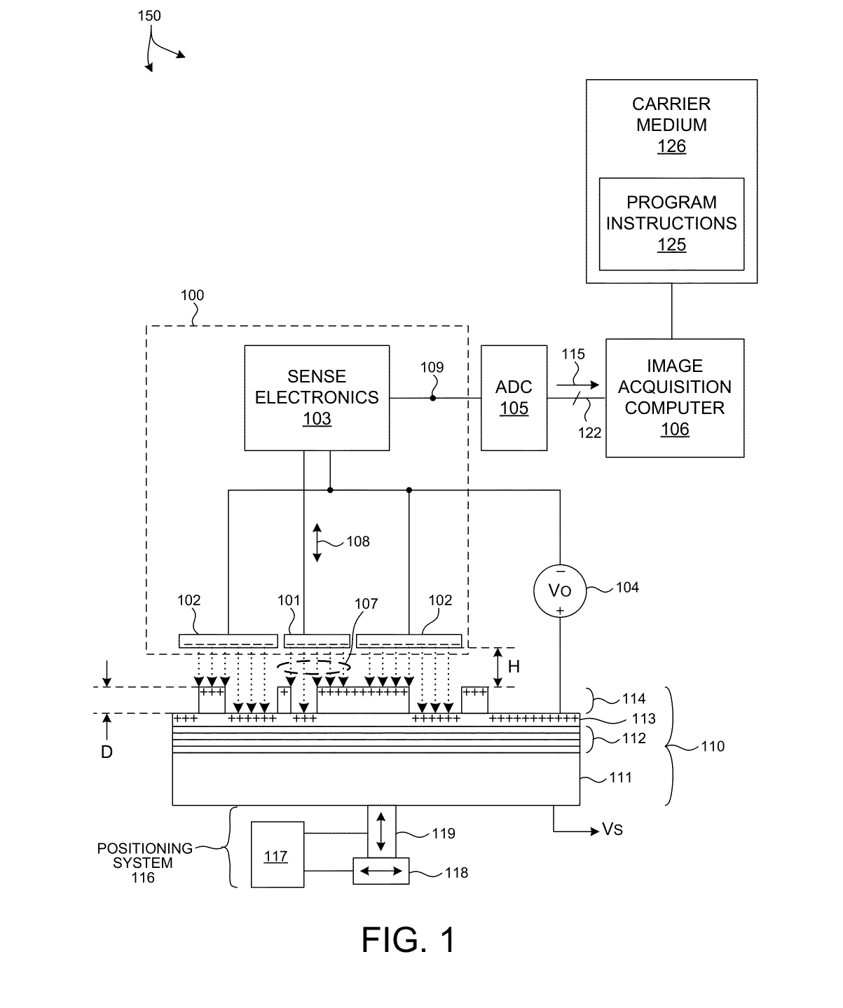

FIG. 1 illustrates a system 150 for detecting pattern defects of a specimen, in accordance with one embodiment of the present invention. As shown in FIG. 1, the system 150 may be used to generate images of the topography of a specimen 110 by sensing the capacitance between a sense electrode 101 of the capacitance sensing integrated circuit 100 and specimen 110 as the specimen is moved beneath the capacitance sensing integrated circuit 100 by positioning system 116.

In one aspect, capacitance sensing integrated circuit is an integrated circuit that includes a number of sense electrodes 101 and sense electronics 103. Capacitance sensing integrated circuit 100 is constructed using modern integrated circuit manufacturing techniques. This allows the sense electrodes to be miniaturized to sizes that enable inspection of reticles and wafers, and in particular, EUV reticles. In some embodiments, a large number of very small sense electrodes are densely packed together. In some embodiments, sense electrode 101 has a sensing surface with an area of less than 100 um² (e.g., 10 micrometers by 10 micrometers). In some embodiments, sense electrode 101 has a sensing surface with an area of less than 0.01 um² (e.g., 100 nanometers by 100 nanometers). In some other embodiments, sense electrode 101 has a sensing surface with an area of less than 0.0004 um² (e.g., 20 nm by 20 nm). Sense electrodes 101 may be sized based on the smallest pitch that can be manufactured by available lithography systems. For example, a 44 nanometer pitch may be achieved by double patterning immersion DUV lithography. A pitch on the order of 20 nanometers may be achieved by self-assembly of block co-polymers or by electron beam writing tools. As semiconductor pattern dimensions shrink with advances in technology, the achievable sensor pitch will also shrink in proportion.

Sense electrodes of such small dimensions enable the inspection of very small patterned features on the surface of a specimen (e.g., an EUV photomask). For example, an EUV photomask may have feature sizes of approximately 80 nanometers. A sense electrode having a sensing surface of less than 0.01 um² may be able to detect pattern defects on this photomask.

In addition, by fabricating the sense electronics 103 in the same integrated circuit as the sense electrodes 101, the electrical connections between the sense electronics 103 and each sense electrode 101 are miniaturized in proportion to the sense electrodes 101. This ensures that there is enough space for densely packed sense electrodes to be electrically addressed. This also ensures that the lengths of the electrical connections are short enough to avoid excessive signal contamination from electrical noise.

As illustrated in FIG. 1, by way of example, the specimen 110 under inspection is an EUV photomask. An EUV photomask is typically built onto a 150 mm×150 mm×5 mm fused silica plate 111. One side of the mask is covered with a multi-layer Bragg reflector 112 made of alternating layers of molybdenum and silicon. The multi-layer reflector 112 is protected by a ruthenium capping layer 113. An absorber film 114 usually made of tantalum-boron-nitride is located above the capping layer 113. The absorber film 114 is patterned using e-beam lithography and plasma etching. The multi-layer reflector 112, the capping layer 113, and the absorber 114 are electrically conductive, thus EUV masks have a continuous, conductive surface. In addition, EUV masks are used without a pellicle, thus the capacitance sensing integrated circuit 100 can be located close to the surface of the EUV photomask for inspection.

In the illustrated example, the specimen under inspection is an EUV photomask. However, other electrically conductive, patterned media may be contemplated (e.g., semiconductor wafers, reticles for use with other lithographic processes, or other patterned media).

As illustrated in FIG. 1, the EUV photomask 110 is scanned underneath the capacitance sensing integrated circuit 100 at a scan velocity, V, by positioning system 116. As illustrated in FIG. 1, positioning system 116 includes a translation stage 118 to move EUV photomask 110 in a direction parallel to the absorber surface of EUV photomask 110. By way of example, translation stage 118 may be a two dimensional linear stage (e.g., xy stage), a two dimensional rotational stage (e.g., r-theta stage), or a one dimensional linear stage. Positioning system 116 may also include a translation stage 119 to move EUV photomask 110 in a direction perpendicular to the absorber surface of EUV photomask 110 to maintain a fixed spacing between the sense electrodes 101 and the surface of EUV photomask 110. As illustrated in FIG. 1, motion controller 117 coordinates the motion of stages 118 and 119.

By maintaining an approximately fixed spacing between the sense electrodes and the surface under inspection, signal changes induced by changes in surface topography will not be contaminated by changes in distance between the sense electrodes 101 and the EUV photomask 110, itself. The space maintained between the sense electrodes 101 and the surface under inspection may be determined based on the size of the sense electrodes 101. For example, the spacing between the sense electrode and the surface under inspection should be less than a major dimension across the face of the sense electrode 101, itself. For example, as illustrated in FIG. 1, if sense electrode 101 is 100 nanometers by 100 nanometers, then the distance, H, between the top of the features of absorber layer 114 and the sense electrode 101 should be less than 100 nanometers. Preferably, the distance, H, should be less than 20 nanometers. In some embodiments, the distance, H, is less than 10 nanometers. Resolution is improved as the distance, H, is reduced, but system complexity may be significantly increased as the fly height is decreased. For some applications, no translation stage 119 is necessary. However, for very small fly heights, a translation stage 119 may be unavoidable. By way of example, translation stage 119 may be a piezoelectric driven flexure stage.

Although, as illustrated in FIG. 1, EUV photomask 110 is moved relative to capacitance sensing integrated circuit 100 by positioning system 116, other architectures may be contemplated. For example, EUV photomask 110 may be fixed and capacitance sensing integrated circuit 100 may be moved over EUV photomask 110 by a positioning system. In another example, EUV photomask 110 may be moved in one direction (e.g., in plane with the surface of EUV photomask 110) and capacitance sensing integrated circuit 100 may be moved in another direction (e.g., out of plane of the surface of EUV photomask 110). Many combinations may be contemplated within the scope of this disclosure.

In the embodiment depicted in FIG. 1, the electrically conductive surface of EUV photomask 110 is held at a voltage potential, V0, with respect to a guard electrode 102 by a constant voltage source 104. In some embodiments, guard electrode 102 is at ground or zero potential. In addition, the sense electrodes 101 are maintained at the same voltage potential as the guard electrode 102 by sense electronics 103. Because the guard electrode 102 and the sense electrodes 101 are maintained at the same voltage potential there is no electric field between them. Thus, electrical charge is present only on surfaces of the electrodes facing the photomask. The surfaces of sense electrodes 101 and guard electrode 102 facing EUV photomask 110 are co-planar. The voltage potential, V0, induces electric fields 107 between the EUV photomask 110 and sense electrodes 101. The electric field generated between the guard electrode 102 and EUV photomask 110 surrounds the electric fields 107 and minimizes their distortion (e.g., spreading, fringing, etc.). In this manner, the electrical field lines of electric field 107 are maintained as uniformly straight as practically possible. The size of the guard electrode may be any practical value. However, in a preferred embodiment, the guard electrode has a surface area that is at least ten times the cumulative surface area of each of the sense electrodes 101.

As illustrated, by way of example, in FIG. 1, the depth, D, of features patterned in the absorber layer 114 of EUV photomask 110 is approximately 60 nanometers (feature heights between 50-75 nanometers are typical). For a constant voltage potential, V0, between sense electrode 101 and EUV photomask 110, the induced electric field 107 is stronger when sense electrode 101 is over the top of a feature and weaker when the electrode is over a trench. The electric potential between two points in a static electric field, E, is given by the line integral

$$Δ V = {\int }_{C} E \cdot d L \qquad ( 1 )$$

where C is an arbitrary path connecting the two points. The path integral from a point on the surface of EUV photomask 110 to a point on a sense electrode 101 is maintained at a constant value, V0, by sense electronics 103. Thus, as the path length increases (e.g., when sense electrode 101 is over a trench), the electric field is reduced to maintain the constant voltage potential, V0. To reduce the electric field, the surface charge density (i.e., the total charge over the fixed area of the sense electrode) must be reduced. In this scenario, to keep the potential of the sense electrode, V0, constant, an electrical current flow 108 transports electrical charge away from the surface of sense electrode 101. Conversely, when the path length decreases (e.g., when sense electrode 101 moves over the top of a feature of absorber layer 114, the electric field is increased to maintain the constant voltage potential, V0. The electric field is increased by increasing the charge on the surface of sense electrode 101. In this scenario, an electrical current flow 108 transports electrical charge toward the surface of sense electrode 101 to increase the charge on the surface of sense electrode 101. A voltage present on output node 109 of sense electronics 103 indicates the charge on the surface of sense electrode 101. Hence, the voltage at the output node 109 indicates whether sense electrode 101 is over a trench or an un-etched portion of absorber layer 114.

The output node 109 is coupled to analog to digital converter (ADC) 105. ADC 105 converts the voltage at output node 109 to a digital signal 115 for further processing by a digital computer. The digital signal 115 is transmitted to an image acquisition computer 106 over a high-speed bus 122. In a preferred embodiment, sense electrodes 101, guard electrode 102, sense electronics 103, ADC 105, multiplexer circuitry (not shown), and bus driver circuitry (not shown) are fabricated as an integrated circuit on the same semiconductor chip. However, as illustrated in FIG. 1, ADC 105, multiplexer circuitry, and bus driver circuitry may be separate from an integrated circuit including sense electrodes 101, guard electrode 102, and sense electronics 103.

As illustrated in FIG. 1, system 150 may include one or more image acquisition computers 106. The one or more computers 106 may be communicatively coupled to the capacitance sensing integrated circuit 100. In one aspect, the one or more computers 106 may be configured to receive a set of measurement signals 115 generated by the capacitance sensing integrated circuit 100. Upon receiving the measurement signals 115, the one or more computers 106 may then determine the presence of a defect in the pattern topography measured by capacitance sensing integrated circuit 100. In this regard, the computing system 116 may perform a die-to-die, cell-to-cell, or die-to-database inspection. For example, when performing a die-to-die or cell-to-cell inspection, computer 106 compares capacitive images of two portions of the EUV photomask 110 that should be identical. If the images differ by more than a pre-determined threshold, a defect in the EUV photomask pattern is detected. In another example, when performing a die-to-database inspection, computer 106 calculates the expected image from a data set that describes the intended pattern on the EUV photomask 110. This data set may be extracted from a database formatted according to any number of industry standards for representing a set of polygon (e.g., Graphic Database System II from Cadence Design Systems, San Jose, Calif., OASIS.MASK® maintained by Semiconductor Equipment and Materials International, San Jose, Calif., or Manufacturing Electron Beam Exposure System (MEBES). Computer 106 solves the Poisson equation to determine the charges induced on the sense electrodes 101 predicts the output voltage signals at the output node 109 of sense electronics 103. Computer 106 compares the expected signal to the actual signal received from capacitance sensing integrated circuit 100. If the difference exceeds a predetermined threshold, a defect on the EUV photomask 110 is detected.

In some examples, computer 106 may be configured to identify defects with the aid of user input. For instance, a topographic image may be presented to a user on a display (not shown), such as a liquid crystal display. The user may then identify defects by entering information into the computer 106 using a user interface device (e.g., mouse, keyboard, trackpad, trackball, touch screen, or the like). In this regard, the user may select, or “tag,” portions of the image pertinent to defect analysis.

It should be recognized that the various steps described throughout the present disclosure may be carried out by a single computer 106 or, alternatively, multiple computers 106. Moreover, different subsystems of the system 150, such as the positioning system 116 and voltage supply 104 may include a computer suitable for carrying out at least a portion of the steps described above. Therefore, the above description should not be interpreted as a limitation on the present invention but merely an illustration. Further, the one or more computers 106 may be configured to perform any other step(s) of any of the method examples described herein.

Computer 106 may be communicatively coupled to the capacitance sensing integrated circuit 100 in any manner known in the art. The computer 106 of the system 150 may be configured to receive and/or acquire data or information from the capacitance sensing integrated circuit 100 by a transmission medium that may include wireline, fiberoptic, and/or wireless portions. In this manner, the transmission medium may serve as a data link between the computer 106 and the capacitance sensing integrated circuit 100. Further, the computer 106 may be configured to receive measurement results via a storage medium (i.e., memory). For instance, the measurement results obtained using the capacitance sensing integrated circuit 100 may be stored in a permanent or semi-permanent memory device. In this regard, the measurement results may be imported from an external system.

The computer 106 may include, but is not limited to, a personal computer system, mainframe computer system, workstation, image computer, parallel processor, or any other device known in the art. In general, the term “computer” may be broadly defined to encompass any device having one or more processors, which execute instructions from a memory medium.

Program instructions 125 implementing methods such as those described herein may be transmitted over or stored on carrier medium 126. The carrier medium may be a transmission medium such as a wire, cable, or wireless transmission link. The carrier medium may also include a computer-readable medium such as a read-only memory, a random access memory, a magnetic or optical disk, or a magnetic tape.

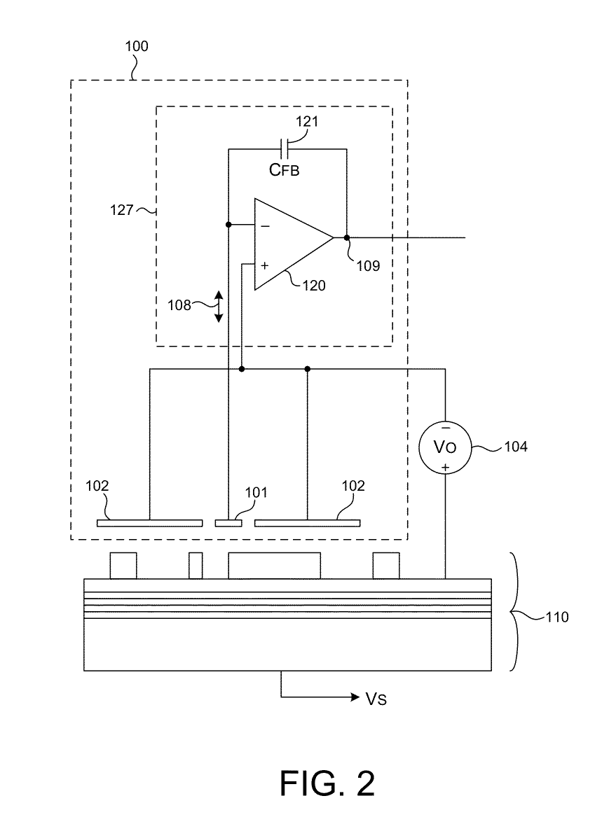

FIG. 2 is illustrative of capacitance sensing integrated circuit 100 in one embodiment. Guard electrode 102 and sense electrodes 101 are coupled to charge amplifier 127. The guard and sense conductors are preferably extended all the way to the input nodes of the charge amplifier 127. Guard electrodes 102 and sense electrodes 101 are metallic contacts (e.g., tungsten, copper, aluminum silicon copper alloy, etc.) common in semiconductor fabrication. A number of charge amplifiers 127 are each individually coupled to a corresponding sense electrode 102. A charge amplifier 127 maintains a sense electrode 101 at the same potential as the guard electrode 102 by operation of a feedback loop including feedback capacitor 121 of operational amplifier 120.

Charge amplifier 127 adjusts the charge on the surface of sense electrode 101 to maintain a constant voltage potential, V0, between the surface of EUV photomask 110 and sense electrode 101. An electrical current flow 108 transports electrical charge to and from the surface of sense electrode 101. A voltage present on output node 109 of operational amplifier 120 indicates the charge on the surface of sense electrode 101. Hence, the voltage at the output node 109 indicates whether sense electrode 101 is over a trench or an un-etched portion of absorber layer 114 as EUV photomask 110 is translated beneath capacitance sensing integrated circuit 100.

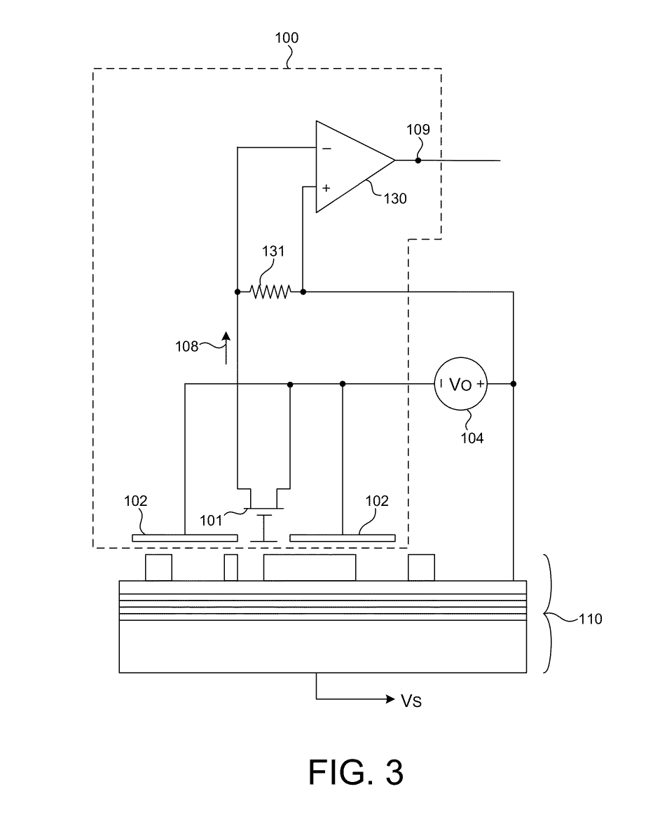

FIG. 3 is illustrative of capacitance sensing integrated circuit 100 in another embodiment. In the illustrated embodiment, sense electrodes 101 are gates of field effect transistors (FET). Guard electrode 102 is illustrated in the depicted embodiment; however, in some other embodiments it may be deleted. In this manner, a guard electrode should be considered an optional element of embodiments that utilize field effect transistors as sense electrodes. The gate of FET 101 is electrically floating (i.e., it is not electrically coupled to an electronic circuit). The capacitance between the EUV photomask 110 and the gate of FET 101, and the capacitance between the gate of FET 101 and its channel form a capacitive voltage divider. The voltage at the gate of the FET 101 is higher when its gate is next to an un-etched feature of the photomask 110. When the potential of the gate changes, the effective resistance of FET 101 changes.

In some embodiments (e.g., the embodiment illustrated in FIG. 3), a resistor 131 is coupled in series with a voltage source 104 and FET 101. As the effective resistance of FET 101 changes, a voltage across resistor 131 changes when current 108 is flowing. This change in voltage is detected by differential amplifier 130. In this manner, a voltage present on output node 109 of operational amplifier 130 indicates the capacitance between the gate of FET 101 and the photomask 110. Hence, the voltage at the output node 109 indicates whether FET 101 is over a trench or an un-etched portion of absorber layer 114 as EUV photomask 110 is translated beneath capacitance sensing integrated circuit 100.

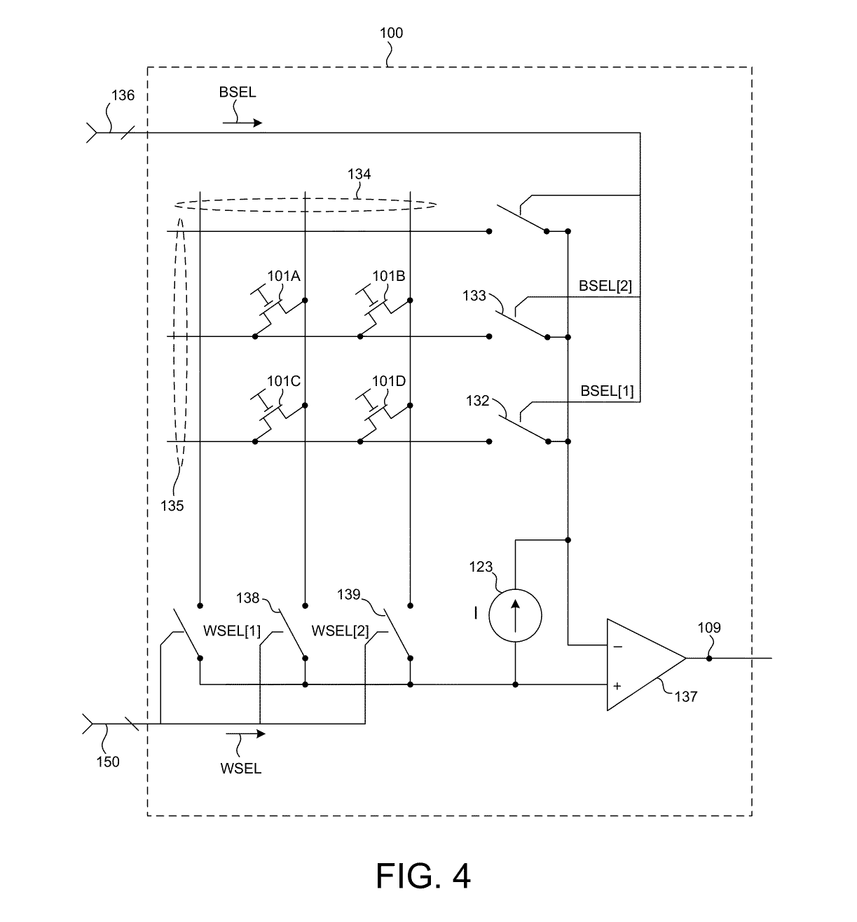

In some other embodiments, voltage source 104 and the resistor 131 are replaced by a current source 123 (illustrated in FIG. 4), and the differential inputs of amplifier 130 are connected to the source and drain of FET 101. A change in voltage across the source and drain of FET 101 is detected by differential amplifier 130. In this manner, a voltage present on output node 109 of differential amplifier 130 indicates the capacitance between the gate of FET 101 and the photomask 110. Hence, the voltage at the output node 109 indicates whether FET 101 is over a trench or an un-etched portion of absorber layer 114 as EUV photomask 110 is translated beneath capacitance sensing integrated circuit 100.

In the aforementioned embodiments, each sense electrode 101 is individually coupled to a corresponding signal amplifier (e.g., charge amplifier 127 or differential amplifier 130). However, in another aspect, a number of sense electrodes are selectively coupled to an individual amplifier. This may be desirable if there is not enough space on the integrated circuit to individually connect each sense electrode to a distinct amplifier circuit.

FIG. 4 is illustrative of an embodiment of a capacitance sensing integrated circuit 100 operable to selectively couple a number of sense electrodes to an individual amplifier. As illustrated in FIG. 4, capacitance sensing integrated circuit 100 includes a two dimensional array of sense electrodes 101. In the depicted embodiment, sense electrodes 101 are FETs. However, in other embodiments, sense electrodes 101 may be metal contacts as described with reference to FIG. 2. The two dimensional array of sense electrodes includes two rows and two columns of sense electrodes 101. However, in general, any number of rows and columns may be contemplated. The rows of the array are addressed by bit lines 135 and the columns are addressed by word lines 134 in a manner similar to modern memory structures (e.g., NAND flash memory). In the depicted embodiment, each sense electrode 101A-D may be individually addressed by selectively coupling the appropriate bit line and word line to the input of differential amplifier 137. In the depicted embodiment, switching elements 132 and 133 selectively couple a corresponding bit line to an inverting input of the differential amplifier 137 and switching elements 138 and 139 selectively couple a corresponding word line to a non-inverting input of the differential amplifier 137. In one embodiment, the switching elements are transistors. A digital control signal, BSEL, is communicated to switching elements 132 and 133 over control line 136. Depending on the value of binary digital control signal BSEL[1], switching element 132 is either substantially conductive or substantially not conductive. Similarly, depending on the value of binary digital control signal BSEL[2], switching element 133 is either substantially conductive or substantially not conductive. In this manner, digital control signal, BSEL, determines which bit line is coupled to differential amplifier 137 at a given time. Similarly, a digital control signal, WSEL, is communicated to switching elements 138 and 139 over control line 150. Depending on the value of binary digital control signal WSEL[1], switching element 138 is either substantially conductive or substantially not conductive. Similarly, depending on the value of binary digital control signal WSEL[2], switching element 139 is either substantially conductive or substantially not conductive. In this manner, digital control signal, WSEL, determines which word line is coupled to differential amplifier 137 at a given time.

In the depicted embodiment, a current source 123 is coupled between the inputs of an amplifier circuit 137 (e.g., differential amplifier 137). The non-inverting input of the differential amplifier 137 is selectively coupled to one of the word lines 134 based on the value of digital signal WSEL. For example, the non-inverting input of differential amplifier 137 is coupled to FET 101A and FET 101C when switching element 138 is conductive. The inverting input of the differential amplifier 137 is selectively coupled to one of the bit lines 135 based on the value of digital signal BSEL. For example, the inverting input of differential amplifier 137 is coupled to FET 101A and FET 101B when switching element 133 is conductive. Thus, when switching elements 138 and 133 are conductive, sense electrode 101A is coupled to differential amplifier 137. In this manner, a single amplifier circuit may be individually coupled to any of an array of sense electrodes based on the values of digital control signals BSEL and WSEL.

As illustrated in FIG. 4, each sense electrode 101 of a two dimensional array of sense electrodes may be individually coupled to a current supply and amplifier circuit. This may be advantageous because it avoids introducing signal variations due to different amplifier gains and current source values by using a single current source and differential amplifier to sequentially measure each sense electrode. However, many other embodiments may be contemplated. For example, a current supply and an amplifier may be fixedly coupled to each row of the array and a sense electrode of each row may be selectively coupled to a corresponding current supply and amplifier by a digital control signal WSEL. In this manner, a sense electrode signal value may be read from each row simultaneously.

As illustrated in FIG. 4, each sense electrode 101 of a two dimensional array of sense electrodes may be individually coupled to a current supply and amplifier circuit. However, in some other embodiments, a voltage supply and resistor coupled in series with a selected sense electrode may also be employed in a manner analogous to the embodiment referenced in FIG. 3.

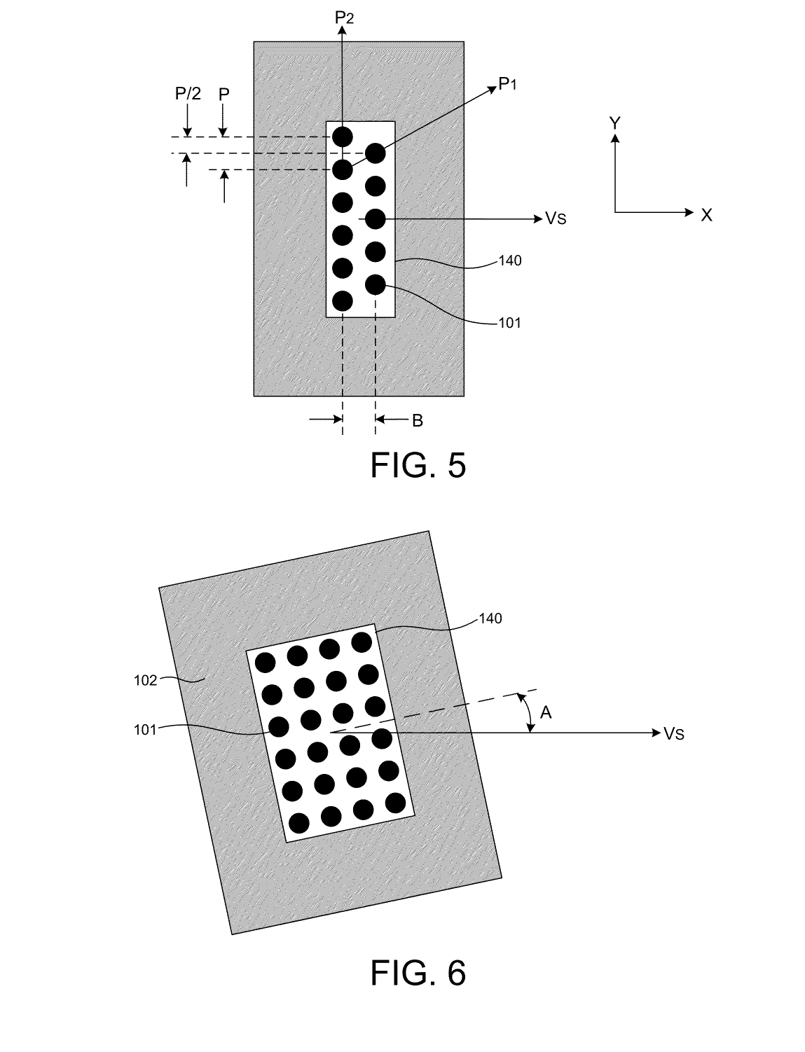

As illustrated in FIGS. 5 and 6, the capacitance sensing integrated circuit 100 includes a two dimensional array 140 of sense electrodes 101. In a given column, each sense electrode 101 is spaced apart from its neighbor by a pitch, P. Each column of sense electrodes 101 is spaced apart from its neighboring column by a distance, B. The minimum achievable separation between sense electrodes is limited to the achievable pitch of the lithographic process. In yet another aspect, the effective resolution of a capacitance sensing integrated circuit is enhanced by offsetting the pattern of sense electrodes, skewing the patterns of sense electrodes relative to the scan direction, or a combination of both.

In the embodiment illustrated in FIG. 5, the array 140 is scanned relative to the photomask in the x-direction, perpendicular to the columns of sense electrodes 101. However, the second column of sense electrodes is offset from the first column of sense electrodes by a distance P/2. If a first column of the array 140 of sense electrodes is sampled at a time, t1, and the second column of sense electrodes is sampled at a time, t2, where the difference between t1 and t2 is the distance, B, divided by the scan velocity, Vs, a portion of the photomask 110 extending in the y-direction will be imaged twice. The portion will be imaged first by the first column of sense electrodes and imaged again by the second column of sense electrodes that are offset in the y-direction from the first column of sense electrodes by the distance, P/2. In this manner, the resolution of the combination of these two images in the y-direction is effectively doubled. Similarly, this resolution enhancement can be extended by adding additional columns, each offset by a fraction of pitch, P.

In general, the array 140 is two dimensional having two pitch vectors p1 and p2. There is an electrode at each position (m p1+n p2) for arbitrary integer values of m and n. To enhance resolution, at least one of the pitch vectors p1 and p2 is not parallel or perpendicular to the scan direction (e.g., pitch vector p1 illustrated in FIG. 5).

In some embodiments, p1 and p2 are orthogonal to each other, but neither are parallel or perpendicular to the scan direction. For example, as illustrated in FIG. 6, pitch vector p1 is skewed from the scan direction by an angle, A. Similarly, this enables imaging of the photomask with a spatial resolution that is smaller than the pitch between adjacent sense electrodes.

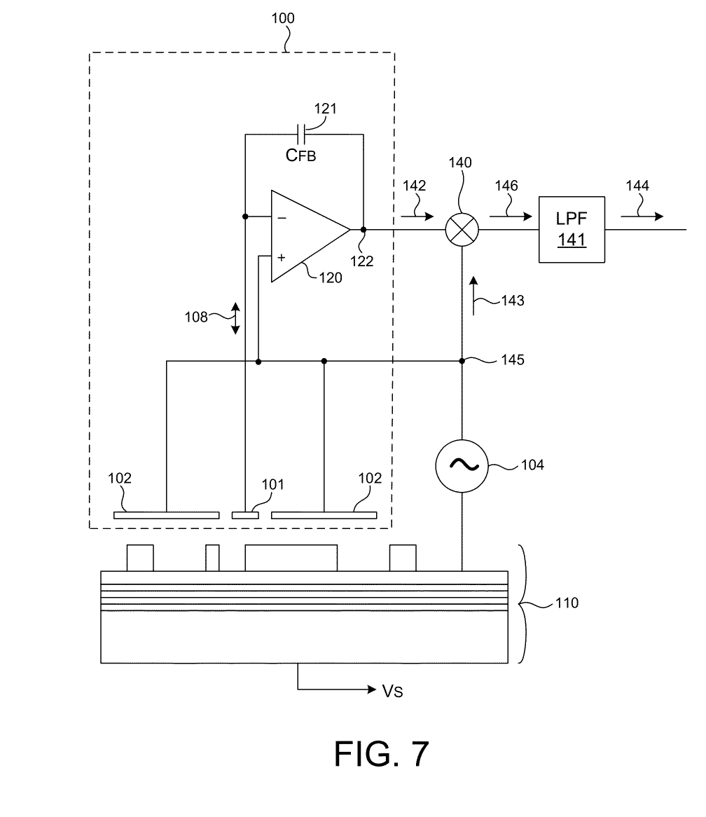

In yet another aspect, homodyne or heterodyne detection of signals generated by capacitance sensing integrated circuit 100 may be employed to reduce measurement noise of capacitance sensing integrated circuit 100. As illustrated in FIG. 7, voltage source 104 is an oscillatory voltage source. The frequency of oscillation is significantly higher than the sampling frequency of ADC 105 to avoid aliasing. An oscillatory voltage present on voltage node 145 is supplied to the sense electronics of capacitance sensing integrated circuit 100 and a mixer 140. Mixer 140 is coupled to the oscillatory voltage source 104, the output of operational amplifier 120, and a low pass filter 141. A signal 142 indicative of changes in charge on the surface of sense electrode 101 is mixed with oscillatory voltage signal 143 by mixer 140. The resulting mixed signal 146 is supplied to low pass filter 141. The resulting filtered signal 144 may be communicated to ADC 115 for further processing as discussed hereinbefore with reference to FIG. 1. A homodyne detection scheme is described with reference to FIG. 7. However, a heterodyne detection scheme may also be contemplated. In a heterodyne scheme, a signal of slightly different frequency would be supplied to the mixer 140 than the signal supplied to the sense electronics. In addition, the low pass filter 141 would be replaced with a band pass filter.

In a preferred embodiment, mixer 140 and low pass filter 141, or alternatively a band pass filter used for heterodyne detection, are fabricated as part of capacitance sensing integrated circuit 100. However, as illustrated in FIG. 7, mixer 140 and low pass filter 141 may be fabricated separately from capacitance sensing integrated circuit 100.

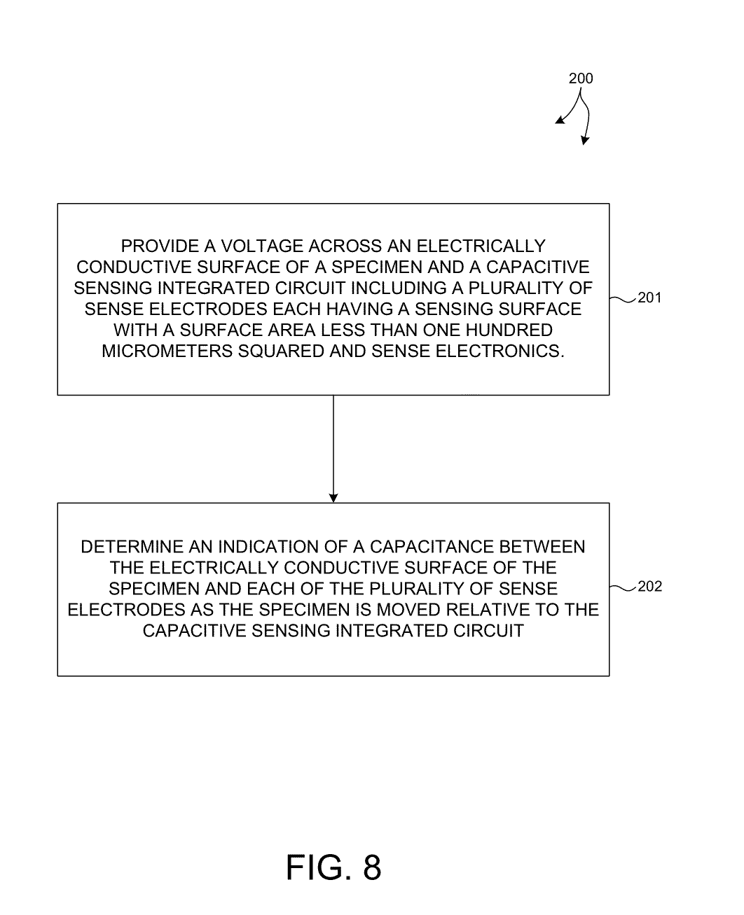

FIG. 8 illustrates a method 200 suitable for implementation by the system 150 of the present invention. In one aspect, it is recognized that data processing steps of the process flow 200 may be carried out via a pre-programmed algorithm executed by one or more processors of computer 106. While the following description is presented in the context of system 150, it is recognized herein that the particular structural aspects of system 150 do not represent limitations and should be interpreted as illustrative only.

In block 201, a voltage is provided across the electrically conductive surface of a specimen 110 and a capacitance sensing integrated circuit 100. The capacitance sensing integrated circuit 100 includes a plurality of sense electrodes 101 each having a sensing surface with a surface area less than one hundred um² (e.g., ten micrometers by ten micrometers). Capacitance sensing integrated circuit 100 also includes sense electronics 103.

The voltage potential, V0, induces electric fields 107 between the specimen 110 and sense electrodes 101. In some examples, the electric field generated between a guard electrode 102 and specimen 110 surrounds the electric fields 107 and minimizes their distortion (e.g., spreading, fringing, etc.). In this manner, the electrical field lines of electric field 107 are maintained as uniformly straight as practically possible. For a constant voltage potential, V0, between each sense electrode 101 and specimen 110, the induced electric field 107 is stronger when a sense electrode 101 is over the top of a feature and weaker when the electrode is over a trench. For a constant charge on the surface of an electrically floating gate of a field effect transistor, the gate voltage changes as distance between the gate and the electrically conductive surface of a specimen changes.

In block 202, an indication of the capacitance between the electrically conductive surface of the specimen 110 and each of the sense electrodes 101 is determined as the specimen 110 is moved relative to the capacitance sensing integrated circuit 100.

In some examples, sense electronics 103 maintain a constant voltage potential, V0, between each sense electrode 101 and specimen 110 as the distance between each sense electrode 101 and the surface of specimen 110 changes. Thus, as the distance increases (e.g., when sense electrode 101 is over a trench), the electric field is reduced to maintain the constant voltage potential, V0. The electric field is reduced by reducing the charge on the surface of sense electrode 101. In this scenario, an electrical current flow 108 transports electrical charge away from the surface of sense electrode 101 to reduce the charge on the surface of sense electrode 101. Conversely, when the distance decreases (e.g., when sense electrode 101 moves over the top of a feature of absorber layer 114, the electric field is increased to maintain the constant voltage potential, V0. The electric field is increased by increasing the charge on the surface of sense electrode 101. In this scenario, an electrical current flow 108 transports electrical charge toward the surface of sense electrode 101 to increase the charge on the surface of sense electrode 101. A voltage present on an output node 109 of sense electronics 103 indicates in the charge on the surface of sense electrode 101 as the sense electrode passes over the varying surface topography of specimen 110.

In some other examples, a constant charge is maintained on an electrically floating gate of a field effect transistor. Sense electronics measure changes in the voltage drop across the source and drain of the FET as the sense electrode passes over the varying surface topography of specimen 110.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although embodiments are described herein with respect to reticles, it is to be understood that the embodiments may be used for characterizing pattern features of another specimen such as a wafer. Many different types of reticles are known in the art, and the terms “reticle,” “mask,” and “photomask” as used herein are intended to encompass all types of reticles known in the art.

As used herein, the term “wafer” generally refers to substrates formed of a semiconductor or non-semiconductor material. Examples of such a semiconductor or non-semiconductor material include, but are not limited to, monocrystalline silicon, gallium arsenide, and indium phosphide. Such substrates may be commonly found and/or processed in semiconductor fabrication facilities.

One or more layers may be formed upon a wafer. For example, such layers may include, but are not limited to, a resist, a dielectric material, a conductive material, and a semiconductor material. Many different types of such layers are known in the art, and the term wafer as used herein is intended to encompass a wafer on which all types of such layers may be formed.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. An apparatus comprising:
a capacitance sensing integrated circuit comprising,
a plurality of sense electrodes each having a sensing surface with a surface area less than one hundred micrometers squared, the capacitance sensing integrated circuit configured to have an electrical voltage between each of the sense electrodes and an electrically conductive, patterned surface of a specimen, and
sense electronics configured to generate a plurality of electrical signals indicative of a change of capacitance between the sensing surface of each of the plurality of sense electrodes and the patterned surface of the specimen as the specimen is moved relative to the plurality of sense electrodes in a direction parallel to the patterned surface of the patterned specimen.

2. The apparatus of claim 1, wherein a distance of at least five nanometers is maintained between the plurality of sense electrodes and the patterned specimen during a scan of the patterned specimen.

3. The apparatus of claim 1, further comprising:
a guard electrode having a surface in plane with the sensing surfaces of the plurality of sense electrodes, the capacitance sensing integrated circuit configured to maintain the guard electrode at the same electrical voltage as the plurality of sense electrodes.

4. The apparatus of claim 1, further comprising:
a computer coupled to the capacitance sensing integrated circuit, the computer configured to receive the plurality of electrical signals from the capacitance sensing integrated circuit and generate an image of a topography of the surface of the patterned specimen.

5. The apparatus of claim 2, wherein a distance of less than one hundred nanometers is maintained between the plurality of sense electrodes and the patterned specimen during a scan of the patterned specimen.

6. The apparatus of claim 2, wherein the distance between the plurality of sense electrodes and the patterned specimen is maintained approximately constant during the scan of the patterned specimen.

7. The apparatus of claim 1, wherein the area of the sensing surface of each of the plurality of sense electrodes is less than 0.01 micrometers squared.

8. The apparatus of claim 1, wherein each of the plurality of sense electrodes is a field effect transistor having an electrically floating gate and a source and a drain coupled to the sense electronics.

9. The apparatus of claim 8, wherein the sense electronics includes,
a resistor coupled between a voltage source and a field effect transistor of the plurality of sense electrodes, and
a differential amplifier having an inverting input and a non-inverting input coupled across the current sensing resistor, and an output node, wherein a voltage present on the output node is indicative of a a gate voltage of the field effect transistor.

10. The apparatus of claim 8, wherein the sense electronics includes,
a current source coupled across the source and the drain of each of the field effect transistors, and
a differential amplifier having an inverting input and a non-inverting input coupled across the source and the drain of each of the field effect transistors, and an output node, wherein a voltage present on the output node is indicative of a gate voltage of the field effect transistor.

11. The apparatus of claim 10, wherein the sense electronics includes a first switching element that selectively couples the current source to a first field effect transistor based on a value of a first control signal, and a second switching element that selectively couples the current source to a second field effect transistor based on a value of a second control signal.

12. The apparatus of claim 11, wherein the first field effect transistor is selected at a first time when a gate of the first field effect transistor is located over a portion of the patterned specimen and a second field effect transistor is selected at a second time after the first time, when a gate of the second field effect transistor is located over the portion of the patterned specimen.

13. The apparatus of claim 1, wherein each of the plurality of sense electrodes are metallic contact posts, and the sense electronics include a charge amplifier coupled to each of the plurality of sense electrodes.

14. A method comprising:
providing a voltage across an electrically conductive surface of a specimen and a capacitance sensing integrated circuit, the capacitance sensing integrated circuit including a plurality of sense electrodes each having a sensing surface with a surface area less than one hundred micrometers squared and sense electronics; and
determining an indication of a capacitance between the electrically conductive surface of the specimen and each of the plurality of sense electrodes as the specimen is moved relative to the capacitance sensing integrated circuit.

15. The method of claim 14, wherein each of the plurality of sense electrodes is a field effect transistor having an electrically floating gate and a source and a drain coupled to the sense electronics.

16. The method of claim 15, wherein the sense electronics includes,
a resistor coupled between a voltage source and a field effect transistor of the plurality of sense electrodes, and
a differential amplifier having an inverting input and a non-inverting input coupled across the current sensing resistor, and an output node, wherein a voltage present on the output node is indicative of a gate voltage of the field effect transistor.

17. The method of claim 15, wherein the sense electronics includes,
a current source coupled across the source and the drain of each of the field effect transistors, and
a differential amplifier having an inverting input and a non-inverting input coupled across the source and the drain of each of the field effect transistors, and an output node, wherein a voltage present on the output node is indicative of a gate voltage of the field effect transistor.

18. The method of claim 14, wherein each of the plurality of sense electrodes are metallic contact posts, and wherein the sense electronics includes a charge amplifier coupled to each of the plurality of sense electrodes.

19. A system comprising:
a capacitance sensing integrated circuit comprising,
a plurality of sense electrodes each having a sensing surface with a surface area less than 0.01 micrometers squared, the capacitance sensing integrated circuit configured to have an electrical voltage between each of the sense electrodes and an electrically conductive specimen, and
sense electronics configured to generate a plurality of electrical signals indicative of a change of capacitance between the sensing surface of each of the plurality of sense electrodes and the surface of the specimen as the specimen is moved relative to the plurality of sense electrodes; and
a computer configured to:
receive a the plurality of electrical signals from the capacitance sensing integrated circuit, and
determine the presence of a defect in the specimen based at least in part on the plurality of electrical signals.

20. The system of claim 17, wherein the determining of the presence of the defect involves any of a die-to-die inspection, a cell-to-cell inspection, or a die-to-database inspection.
